(19) United States
(12) Patent Application Publication
(10) Pub. No.: US 2003/0035278 A1
(43) Pub. Date: Feb. 20, 2003

(54) Partitioned circuit assembly

(76) Inventors: Daniel A. Lawlyes, Kokomo, IN (US); David Paul Buehler, Delphi, IN (US)

Correspondence Address: Jimmy L. Funke, Delphi Technologies, Inc., Legal Staff Mail Code CT10C, P.O. Box 9005, Kokomo, IN, 46904-9005, US

(21) Appl. No.: 09/928,884

(22) Filed: Aug. 14, 2001

(51) Int. Cl. H05K 7/14

(52) U.S. Cl. 361/796

(57) ABSTRACT

A circuit assembly 10 is provided, including a main assembly board 18, a main assembly housing 20, and at least one partitioned circuit assembly 14. The partitioned circuit assembly 14 includes the partitioned circuit element 22, a partitioned circuit housing 24 and a plurality of connectors 26.

### TECHNICAL FIELD

The present invention relates generally to a partitioned circuit assembly and more particularly, to a partitioned circuit assembly with increased design flexibility.

### BACKGROUND OF THE INVENTION

The cornerstone of success in product development is often the ability of a design to adapt to varying requirements without necessitating a complete redesign of the product. Nowhere has this become more self-evident than in the electronics field. Designs within the electronics field must often be modified to accommodate a variety of different applications. These modifications, however, must often be accomplished without producing a negative increase on the time and costs associated with design and manufacturing.

Advances in the field of automotive electronics has taken steps to address such concerns as well as bring about reductions in design and manufacturing times. One such advancement has taken place in the area of engine controller design. Certain circuits within an engine controller are considered building blocks and are designed, reviewed and approved for use across a variety of different products. During the design process, these building block circuits are integrated into an overall product design in order to reduce the design time for a given application.

Although the conceptual design approach of reusing individual circuit schematics within multiple product designs has resulted in decreased design time and improved design efficiency, the resulting product manufacturing assembly has remained substantially unaltered. It would be highly desirable to take the building block philosophy that has proven successful in improving the design phase of automotive electronics and apply it to the manufacturing and assembly processes. In this way, the manufacturing assembly of the electronic component will share the same improvements in efficiency, cost reduction, and design flexibility already witnessed within the design phase.

It would therefore be highly desirable to have a circuit assembly with a physical layout and construction that adopts the building block philosophy normally applied in the design phase and applies it to result in increased design flexibility within the manufacturing and assembly phase.

It is, therefore, an object of the present invention to provide an electronic assembly with partitioned circuits for increased design flexibility.

In accordance with the object of the present invention, a circuit assembly is provided including a main assembly board and a main assembly housing. The circuit assembly further includes at least one partitioned circuit assembly including a partitioned circuit element, a partitioned circuit housing, and a plurality of connectors. The circuit assembly is placed in communication with the main circuit assembly by way of the plurality of connectors. In this fashion, the circuit assembly may be quickly and efficiently modified by plugging in different partitioned circuit assemblies.

Other objects and features of the present invention will become apparent when viewed in light of the detailed description of the preferred embodiment when taken in conjunction with the attached drawings and appended claims.

### BRIEF DESCRIPTION OF THE DRAWINGS

FIG. 1 is an illustration of an embodiment of a circuit assembly in accordance with the present invention;

FIG. 2 is an exploded view of the circuit assembly illustrated in FIG. 1;

FIG. 3 is a cross-sectional illustration for an embodiment of a partitioned circuit assembly in accordance with the present invention; and

FIG. 4 is an exploded view of the partitioned circuit assembly illustrated in FIG. 3.

### DESCRIPTION OF THE PREFERRED EMBODIMENT(S)

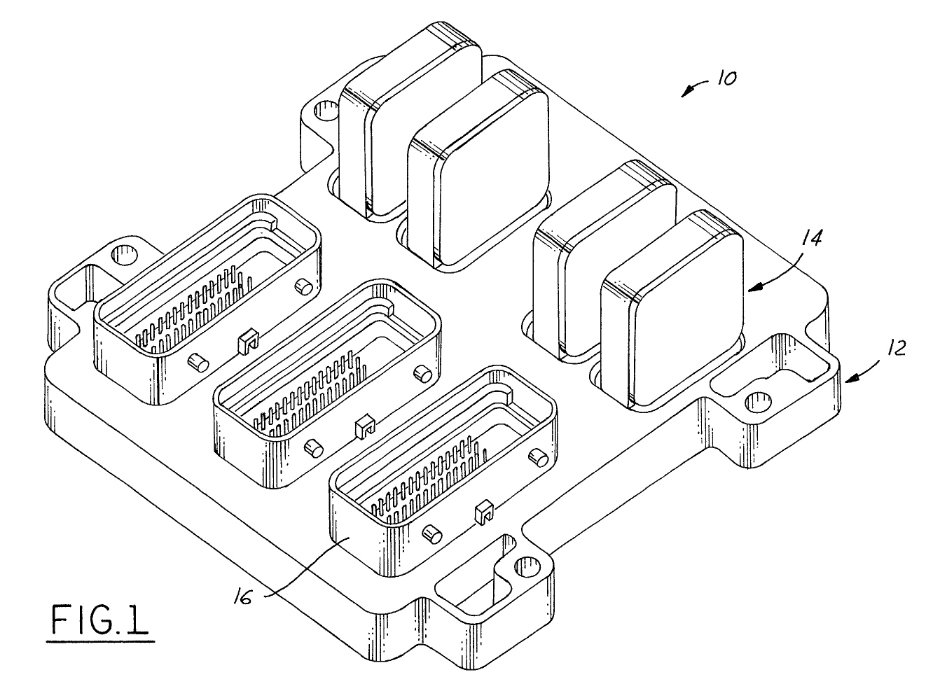

Referring now to FIG. 1 which is an illustration of an embodiment of a circuit assembly in accordance with the present invention.

The circuit assembly 10 is considered for use as an automotive engine controller, however, a wide variety of applications are contemplated for the present invention. The circuit assembly 10 includes a main assembly 12 and at least one partitioned circuit assembly 14. Although a variety of layouts and configurations are contemplated for the circuit assembly 10, one embodiment of the circuit assembly 10 also includes at least one communication port 16 which can be used to allow the circuit assembly 10 to communicate with other systems.

It is well known in the prior art that circuit assemblies for given applications may use common circuits as building blocks to an overall design. The unique aspect of the present invention is to produce these building blocks in small, cost-effective and common packages for standardization. The partitioned assembly 14 represents such packages. The partitioned circuit assembly 14 allows for common circuits to be independently produced as partitioned circuit assembly 14 and installed in a variety of circuit assembly 10 with differing applications. In addition, the use of the partitioned circuit assembly 14 may be utilized to add functions to the main circuit assembly 12. The partitioned circuit assembly 14, therefore, allow for reuse of individual circuits across different product lines as well as allow for quick and efficient modification of the circuit assembly 10. It is contemplated, that the size and configuration of the partitioned circuit assembly 14 may be determined by a variety of factors or functional purpose. Although several sizing factors have been listed, it should be understood that a wide variety of factors, including hybrid circuit density, multiple count, power, logical schematics, and functional purpose, may be considered in determining the precise formation of the partitioned circuit assembly 14.

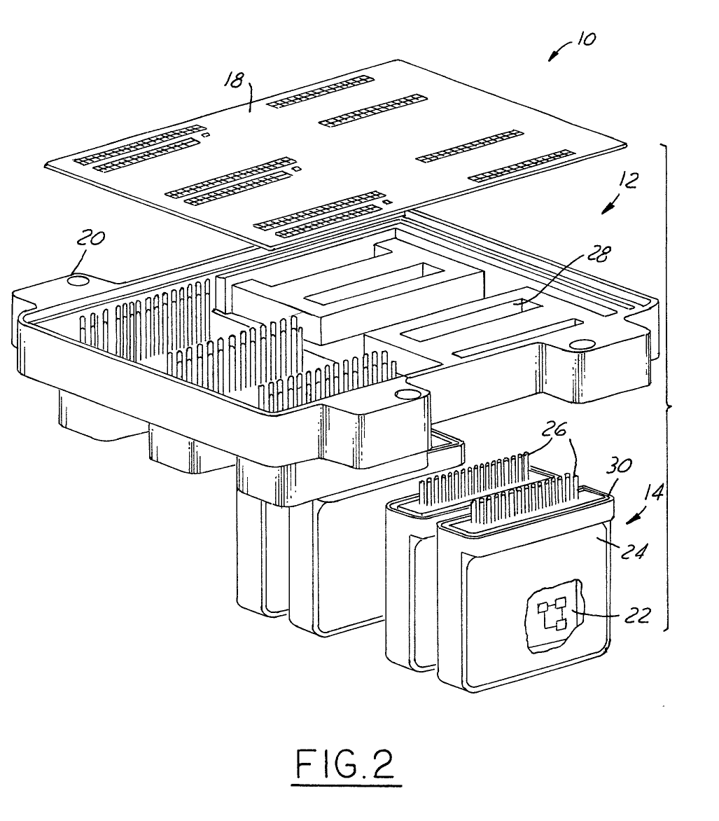

Although a variety of configurations for the main circuit assembly 12 and at least one partitioned circuit assembly 14 are contemplated by the present invention, in one embodiment illustrated in FIG. 2, one configuration is illustrated. A main assembly 12 includes a main assembly board 18 and a main assembly housing 20. The partitioned circuit assembly 14 for assembly use includes a partitioned circuit element 22, a partitioned circuit housing 24 and a plurality of connectors 26. The partitioned circuit assembly 14 are plugged into main assembly ports 28 in the main assembly housing 20 and a plurality of connectors 26 act as a means of communication between partitioned circuit element 22 and the main assembly board 18. In one embodiment, the partitioned circuit assembly 14 is attached to the main board 18 permanently through the use of solder. In other embodiments, however, the partitioned circuit assembly 14 may be detachable from the main assembly board 18 after installation to allow both upgrades and replacement. In still another embodiment, the partitioned circuit assembly 14 may also include a seal element 30 to seal the partitioned circuit assembly 14 to the main assembly 12. This is particularly useful when the circuit assembly 10 is intended for use in a harsh environment where exposure of the circuits may harm the operation of the circuit assembly 10.

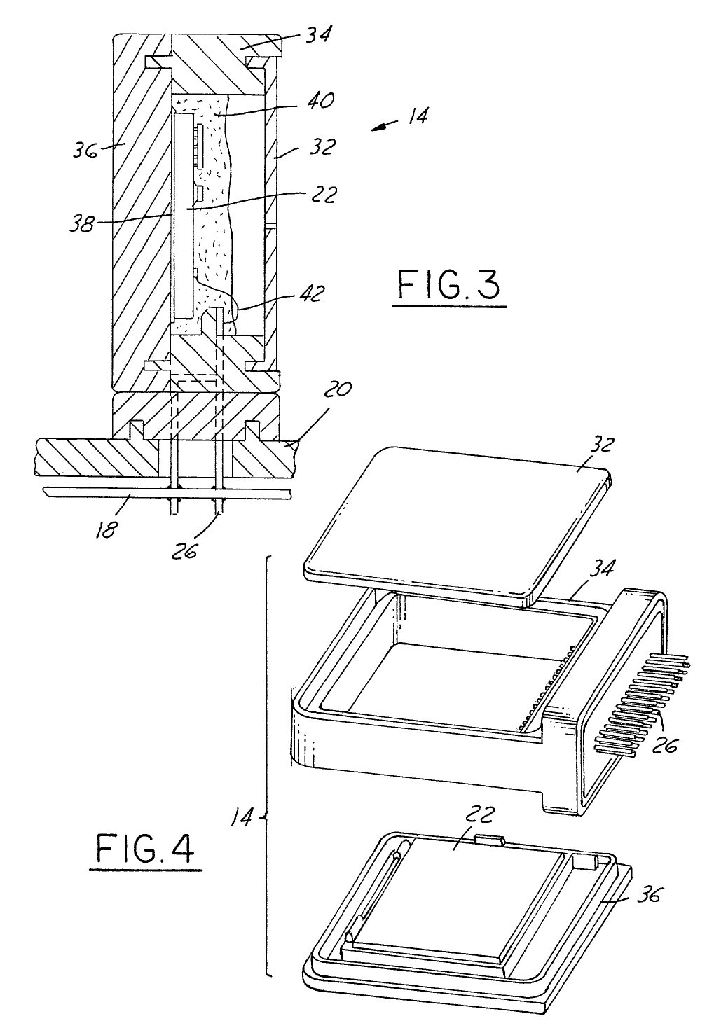

Although a basic description of the partitioned circuit assembly 14 has been described, a cross sectional view of a detailed embodiment is illustrated in FIG. 3. In this detailed embodiment, the housing 24 of the partitioned circuit assembly 14 consists of a partitioned housing cover 32, a partitioned housing side structure 34 and a partitioned back plate 36. In one embodiment, it is preferably that the partitioned housing back plate 36 consists of a heat sink and thereby provide the partitioned circuit assembly 14 with cooling independent of the rest of the circuit assembly 10. This may be particularly beneficial for circuit assemblies generating excess heat. These heat generating circuits can be housed in a partitioned circuit assembly 14 and independently cooled, while protecting other circuitry within the circuit assembly 10 from damage due to their generated heat. It is contemplated that a thermal adhesive 38 can be used to attach the partitioned circuit element 22 to the heat sink back plate 36 such that the partitioned circuit element 22 is put into thermal communication with the heat sink 36.

The partitioned circuit assembly 14 may also include passivation material 38 surrounding the partitioned circuit element 22. This is particularly useful if the partitioned circuit assembly 14 is intended for use in a hostile environment. Wires 42 such as wirebonds, may be used to place the partitioned circuit element 22 in communication with the plurality of connectors 26. An exploded view of the partitioned circuit assembly 14 is illustrated in FIG. 4 for further reference.

In one embodiment, it is contemplated that the plurality of connectors 26 will take on a standard configuration to allow for universal mating with the main assembly board 18. In one of such embodiments, the plurality of connectors 26 may consist of a 32 pin standard connector. In another contemplated embodiment, the plurality of connectors 26 may embody a 16 pin standard connector. It should be understood, however, that these two embodiments are strictly given for illustration purposes and are not intended to serve as a limitation on the present invention. Likewise, while a particular embodiment of the partitioned circuit assembly 14 has thus far been described in significant detail, it should be understood that the form of the partitioned circuit assembly 14 within a larger circuit assembly 10 can take on a wide variety of configurations all contemplated on the present invention.

While particular embodiments of the invention has been shown and described, numerous variations and alternative embodiments will occur to those skilled in the art. Accordingly, it is intended that the invention be limited to only in terms to the appended claims.

What is claimed is:

1. A circuit assembly comprising:
a main assembly board;
a main assembly housing; and
a pre-assembled partition circuit assembly having a partitioned circuit element mounted within a partitioned circuit housing and a plurality of connectors, said plurality of connectors placing said partitioned circuit element in communication with said main assembly board when said partitioned circuit assembly is inserted into said main assembly board.

2. A circuit assembly as described in claim 1 wherein said partitioned circuit assembly further includes a heat sink element.

3. A circuit assembly as described in claim 1 wherein said partitioned circuit assembly further includes passivation material positioned within said partitioned circuit housing.

4. A circuit assembly as described in claim 1 wherein said partitioned circuit assembly further includes a seal element such that said partitioned circuit assembly becomes sealed to said main assembly housing after said partitioned circuit assembly is inserted into said main assembly board.

5. A circuit assembly as described in claim 1 wherein said partitioned circuit assembly further includes a heat sink element, said partitioned circuit element mounted to said heat sink element using thermally conductive material.

6. A circuit assembly as described in claim 1 wherein said main assembly housing includes at least one main assembly port, said at least one main assembly port allowing said partitioned circuit assembly to be inserted into said main assembly board through main assembly housing.

7. A circuit assembly as described in claim I further comprising at least one communication port therein.

8. An engine controller comprising:
a main assembly board;
a main assembly housing; and
a pre-assembled partition circuit assembly having a partitioned circuit element mounted within a partitioned circuit housing and a plurality of connectors, said plurality of connectors placing said partitioned circuit element in communication with said main assembly board when said partitioned circuit assembly is inserted into said main assembly board.

9. An engine controller as described in claim 8 wherein said partitioned circuit assembly further includes a heat sink element.

10. An engine controller as described in claim 8 wherein said partitioned circuit assembly further includes passivation material positioned within said partitioned circuit housing.

11. An engine controller as described in claim 8 wherein said partitioned circuit assembly further includes a seal element such that said partitioned circuit assembly becomes sealed to said main assembly housing after said partitioned circuit assembly is inserted into said main assembly board.

12. An engine controller as described in claim 8 wherein said partitioned circuit assembly farther includes a heat sink element, said partitioned circuit element mounted to said heat sink element using thermally conductive material.

13. An engine controller as described in claim 8 wherein said main assembly housing includes at least one main assembly port, said at least one main assembly port allowing said partitioned circuit assembly to be inserted into said main assembly board through main assembly housing.

14. An engine controller as described in claim 8 further comprising at least one communication port therein.

15. A partitioned circuit assembly for integration into an engine controller comprising:
a partitioned circuit element;
a partitioned circuit housing surrounding said partitioned circuit element; and
a plurality of connectors.

16. A partitioned circuit assembly as described in claim 15 wherein said partitioned circuit housing includes a heat sink portion, said partitioned circuit element being mounted to said heat sink portion using a thermal connective adhesive.

17. A partitioned circuit assembly as described in claim 15 wherein the partitioned circuit assembly may be removably mounted to the engine controller.
